(19) United States
(12) Patent Application Publication
(10) Pub. No.: US 2024/0120194 A1
(43) Pub. Date: Apr. 11, 2024

(54) WAFER PROCESSING SYSTEM

(71) Applicant: SAMSUNG ELECTRONICS CO., LTD., Suwon-si (KR)

(72) Inventors: Sang Min LEE, Suwon-si (KR); Sang Woo BAE, Suwon-si (KR); Sung-Wook JUNG, Suwon-si (KR)

(21) Appl. No.: 18/377,500

(22) Filed: Oct. 6, 2023

(30) Foreign Application Priority Data
Oct. 11, 2022 (KR) 10-2022-0129838
Mar. 6, 2023 (KR) 10-2023-0029150

(51) Int. Cl. H01L 21/02; G02B 27/14; G02B 27/28; H01L 21/687

(52) U.S. Cl. CPC H01L 21/02266; G02B 27/145; G02B 27/283; H01L 21/68714

(57) ABSTRACT

A wafer processing system includes an optical apparatus including a beam splitter configured to receive a laser beam and to split the laser beam into a first beam in a first state of linear polarization and a second beam in a second state of linear polarization; and a beam delayer configured to delay the second beam so that a pulse of the second beam has a delay time with respect to a pulse of the first beam.

### CROSS-REFERENCE TO RELATED APPLICATIONS

This application claims priority from Korean Patent Application No. 10-2022-0129838, filed on Oct. 11, 2022, and No. 10-2023-0029150, filed on Mar. 6, 2023, in the Korean Intellectual Property Office, and all the benefits accruing therefrom under 35 U.S.C. 119, the contents of which in their entireties are herein incorporated by reference.

### BACKGROUND

### 1. Technical Field

The present disclosure relates to a wafer processing system including the same.

### 2. Description of the Related Art

In general, a semiconductor element may be formed through a plurality of unit processes. For example, the unit processes may include a thin film depositing process, a photolithography process, an etching process, an ion implanting process, and an annealing process. Among them, the annealing process may be a process of stabilizing a substrate or a thin film disposed on the substrate or melting the substrate to remove seaming defects in the thin film. For example, the annealing process may include a rapid heat treating process and a laser annealing process.

### SUMMARY

According to an embodiment of the present disclosure, a wafer processing system includes an optical apparatus including a beam splitter and a beam delayer, wherein: the beam splitter is configured to receive a laser beam and to split the laser beam into a first beam in a first state of linear polarization and a second beam in a second state of linear polarization; and the beam delayer is configured to delay the second beam so that a pulse of the second beam has a delay time with respect to a pulse of the first beam.
a beam splitting unit receiving a laser beam and splitting the laser beam into a first beam in a first state of linear polarization and a second beam in a second state of linear polarization; and a beam delaying unit delaying the second beam so that a pulse of the second beam has a delay time with respect to a pulse of the first beam.

According to an embodiment of the present disclosure, a wafer processing system includes a stage on which a wafer is provided; a first light source generating a first laser beam; a first optical apparatus receiving the first laser beam and outputting a first beam and a second beam; an illumination optics homogenizing the first beam and the second beam to generate homogenized beams; and an imaging optics imaging the homogenized beams on the wafer, wherein the first beam is in a first state of linear polarization, the second beam is in a second state of linear polarization, and the first beam and the second beam have a delay time therebetween.

According to an embodiment of the present disclosure, a wafer processing system includes a stage on which a wafer is provided; a light source generating a laser beam; an optical apparatus receiving the laser beam and outputting a first beam and a second beam; an illumination optics homogenizing the first beam and the second beam to generate homogenized beams; and an imaging optics imaging the homogenized beams on the wafer, wherein the optical apparatus includes: a beam splitting unit splitting the laser beam into the first beam and the second beam; and a beam delaying unit delaying the second beam so that a pulse of the second beam has a delay time with respect to a pulse of the first beam, and the beam delaying unit is movable so as to adjust a distance between the beam splitting unit and the beam delaying unit.

### BRIEF DESCRIPTION OF THE DRAWINGS

Features will become apparent to those of skill in the art by describing in detail exemplary embodiments with reference to the attached drawings, in which:

FIG. 1 is a diagram for describing a wafer processing system according to some embodiments;

FIG. 2 is a diagram for describing an optical apparatus according to some embodiments;

FIG. 3 is a graph illustrating a pulse of a laser beam;

FIG. 4 is a graph illustrating pulses of a first-first beam and a first-second beam;

FIG. 5 is a diagram for describing an optical apparatus according to some embodiments;

FIG. 6 a diagram for describing an optical apparatus according to some embodiments;

FIG. 7 a diagram for describing an optical apparatus according to some embodiments;

FIG. 8 a diagram for describing an optical apparatus according to some embodiments;

FIG. 9 is a diagram for describing an optical apparatus according to some embodiments;

FIGS. 10 to 13 are views for describing optical apparatuses according to some embodiments;

FIG. 14 is a graph illustrating pulses of second-first to second-fourth beams;

FIG. 15 is a diagram for describing a wafer processing system according to some embodiments; and

FIGS. 16 to 18 are views for describing optical apparatuses according to some embodiments.

### DETAILED DESCRIPTION

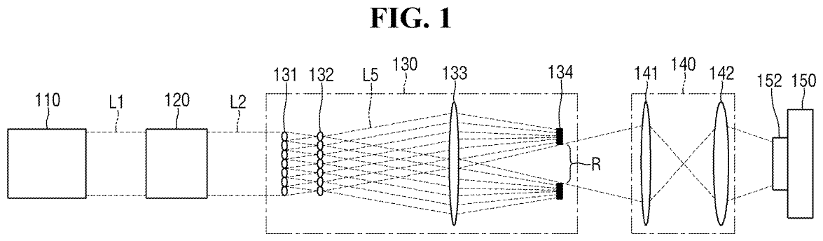

FIG. 1 is a diagram for describing a wafer processing system according to some embodiments.

Referring to FIG. 1, a wafer processing system according to some embodiments may include a first light source 110, a first optical apparatus 120, an illumination optics 130, an imaging optics 140, and a stage 150.

The first light source 110 may generate and output a laser beam L1. The first light source 110 may generate a pulse laser beam L1. The laser beam L1 is a pulse lasting for a very short time and may be repeatedly irradiated. The first light source 110 may be configured to output, e.g., a nano-second pulsed laser, a pico-second pulsed laser, or a femto-second pulsed laser.

The first optical apparatus 120 may receive the laser beam L1 from the first light source 110. The first optical apparatus 120 may split the laser beam L1 and generate and output a plurality of laser beams L2 having a delay time therebetween.

The illumination optics 130 may receive the plurality of laser beams L2 having the delay time therebetween from the first optical apparatus 120. The illumination optics 130 may mix and homogenize the plurality of laser beams L2 with each other. The illumination optics 130 may mix and homogenize the plurality of laser beams L2 having a Gaussian distribution with each other to convert the plurality of laser beams L2 into laser beams L5 having a uniform distribution. The illumination optics 130 may output the laser beams L5 having a flat-top form.

For example, the illumination optics 130 may include array lenses 131 and 132, a condenser lens 133, and masks 134. For example, as illustrated in FIG. 1, the condenser lens 133 may be between the masks 134 and the array lenses 131 and 132.

In detail, the array lenses 131 and 132 may be disposed between the first optical apparatus 120 and the condenser lens 133. The array lenses 131 and 132 may be disposed as a pair. For example, the array lenses 131 and 132 may include a first array lens 131 and a second array lens 132. Each of the first array lens 131 and the second array lens 132 may be, e.g., a fly-eye lens. Each of the first array lens 131 and the second array lens 132 may have a plurality of lens cells. The plurality of lens cells may split each of the laser beams L2 provided from the first optical apparatus 120 into a plurality of laser beams L5.

The condenser lens 133 may be disposed between the array lenses 131 and 132 and the masks 134. The condenser lens 133 may condense the plurality of laser beams L5 emitted from the first and second array lens 131 and 132 into an illumination area R.

The masks 134 may be disposed between the condenser lens 133 and the imaging optics 140. The masks 134 may adjust beam sizes and/or shapes of the laser beams L5. The masks 134 may transmit portions having a uniform intensity among the laser beams L5 therethrough. The laser beams L5 passing through the masks 134 may be provided to the illumination area R. In general, since steepness of edge portions of the laser beams L5 is very great, defects may occur at the edge portions of the laser beams L5 when the laser beams L5 are directly used in a wafer annealing process (e.g., without the masks 134). However, since the edge portions of the laser beams L5 may be blocked by the masks 134, flat-top beams of which edge portions are sharp and uniform may be provided to the illumination area R.

The imaging optics 140 may be disposed between the illumination optics 130 and the stage 150. The imaging optics 140 may provide the beams from the illumination optics 130 onto a wafer 152. For example, the imaging optics 140 may include a first lens 141 and a second lens 142.

The first lens 141 may be disposed between the masks 134 and the second lens 142. For example, the first lens 141 may magnify and project the homogenized laser beams L5 provided from the illumination optics 130. The first lens 141 may include, e.g., a concave lens.

The second lens 142 may be disposed between the first lens 141 and the stage 150. For example, the second lens 142 may reduce and project the homogenized laser beams L5 passing through the first lens 141 onto the wafer 152 on the stage 150. The second lens 142 may include, e.g., a convex lens.

The wafer 152 may be disposed on the stage 150. The stage 150 may move the wafer 152. The wafer processing system may be, e.g., a system that performs annealing on the wafer 152.

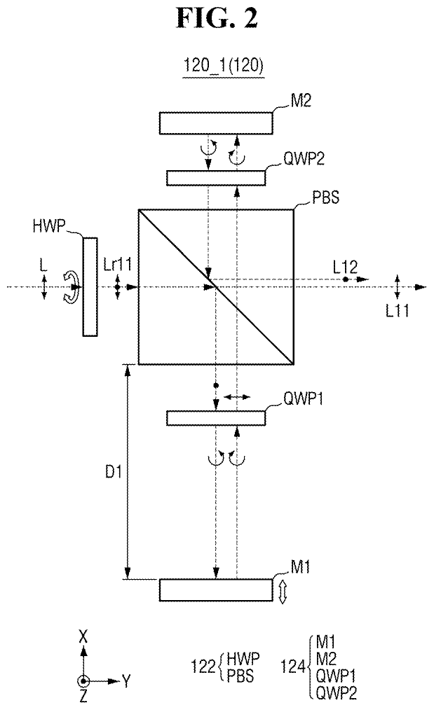

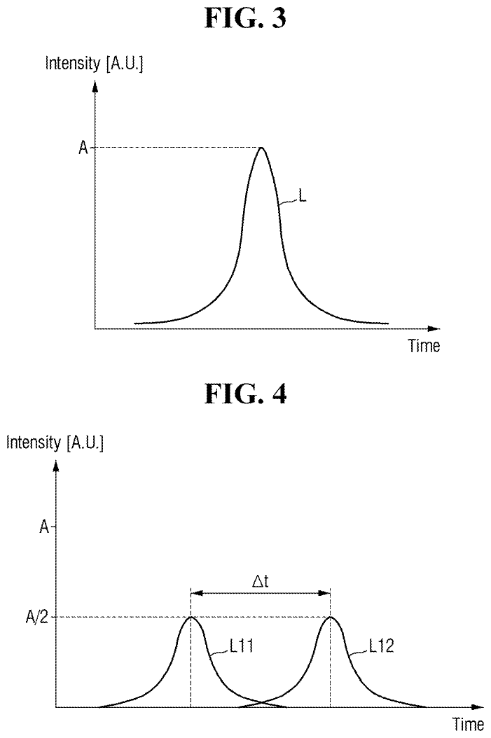

FIG. 2 is a diagram for describing the optical apparatus 120 according to some embodiments. FIG. 3 is a graph illustrating a pulse of a laser beam. FIG. 4 is a graph illustrating pulses of a first-first beam and a first-second beam.

Referring to FIG. 2, the first optical apparatus 120 according to some embodiments may include an optical module 120_1. The first optical apparatus 120 may include one optical module 120_1. The optical module 1201 may include a beam splitting unit 122 (e.g., a beam splitter) and a beam delaying unit 124 (e.g., a beam delayer). The optical module 120_1 may receive a laser beam L and output a first-first beam L11 and a first-second beam L12. The laser beam L1 of FIG. 1 corresponds to the laser beam L of FIG. 2, and the laser beams L2 of FIG. 1 correspond to the first-first beam L11 and first-second beam L12 of FIG. 2.

The beam splitting unit 122 may receive the laser beam L and split the laser beam L into the first-first beam L11, which is in a first state of linear polarization, and the first-second beam L12, which is in a second state of linear polarization. The beam splitting unit 122 may output the first-first beam L11 and the first-second beam L12 to different paths. The first-second beam L12 may be selectively provided to the beam delaying unit 124. The first-first beam L11 may be provided to the illumination optics 130 through the beam splitting unit 122, and the first-second beam L12 may be provided to the illumination optics 130 through the beam splitting unit 122 and the beam delaying unit 124. The beam delaying unit 124 may delay the first-second beam L12 so that a pulse of the first-second beam L12 has a delay time with respect to a pulse of the first-first beam L11.

The beam splitting unit 122 according to some embodiments may include a wave plate HWP and a polarizing beam splitter PBS. For example, the wave plate HWP and the polarizing beam splitter PBS may be arranged in a second direction Y.

The wave plate HWP may receive the laser beam L and change a polarization state of the laser beam L to generate a first changed beam Lr11. The first changed beam Lr11 may include the first-first beam L11 and the first-second beam L12. The first-first beam L11 may be a p-polarization component of the first changed beam Lr11 vibrating in a direction parallel to an incident surface of the first changed beam Lr11, e.g., in a first direction X, and the first-second beam L12 may be an s-polarization component of the first changed beam Lr11 vibrating in a direction perpendicular to the incident surface of the first changed beam Lr11, e.g., in a third direction Z. That is, the first-first beam L11 may be in the first state of the linear polarization and the first-second beam L12 may be in the second state of the linear polarization. Hereinafter, the first state of the linear polarization may be a p-polarization state, and the second state of the linear polarization may be an s-polarization state.

The wave plate HWP may be a half-wave plate. When an optical axis of the wave plate HWP and a polarization direction of the beam incident on the wave plate HWP form an angle of θ, the wave plate HWP may rotate the polarization direction of the beam incident on the wave plate HWP by an angle of 2θ and output the beam of which the polarization direction is rotated.

For example, the wave plate HWP may receive the laser beam L, which is in the first state of the linear polarization. The optical axis of the wave plate HWP may form an angle of 22.5° with respect to a polarization direction of the laser beam L. That is, the optical axis of the wave plate HWP may form an angle of 22.5° with respect to the first direction X. The wave plate HWP may generate the first changed beam Lr11 by rotating the polarization direction of the laser beam L by 45°.

Referring to FIG. 1, the first light source 110 may output, e.g., the laser beam L, which is in the first state of the linear polarization. As another example, an optical element may be disposed between the first light source 110 and the beam splitting unit 122, and the laser beam output from the first light source 110 may have the first state of the linear polarization by the optical element.

Referring to FIG. 2 again, the wave plate HWP may be rotatable. The wave plate HWP may be rotatable on a plane including the first direction X and the third direction Z. By the rotation of the wave plate HWP, a degree of change of a polarization state of the first changed beam Lr11 may be adjusted and a maximum intensity of the pulse of the first-first beam L11 and a maximum intensity of the pulse of the first-second beam L12 may be adjusted. A ratio between the maximum intensity of the pulse of the first-first beam L11 and the maximum intensity of the pulse of the first-second beam L12 may be adjusted by the wave plate HWP.

Referring to FIGS. 3 and 4, a maximum intensity A/2 of the pulse of the first-first beam L11 may be the same as a maximum intensity A/2 of the pulse of the first-second beam L12. The maximum intensity A/2 of the pulse of the first-first beam L11 and the maximum intensity A/2 of the pulse of the first-second beam L12 may be half of a maximum intensity A of the pulse of the laser beam L.

Referring to FIG. 2 again, the polarizing beam splitter PBS may receive the first changed beam Lr11. The polarizing beam splitter PBS may split the first changed beam Lr11 into the first-first beam L11 and the first-second beam L12.

The polarizing beam splitter PBS may provide the first-first beam L11 and the first-second beam L12 to different optical paths. The polarizing beam splitter PBS may transmit a beam, which is in the first state of the linear polarization, therethrough and reflect a beam, which is in the second state of the linear polarization. The polarizing beam splitter PBS may transmit the first-first beam L11 therethrough and reflect the first-second beam L12. The first-first beam L11, which is in the first state of the linear polarization, may pass through the polarizing beam splitter PBS and be then output.

Referring to FIGS. 3 and 4, the first-second beam L12 reflected by the polarizing beam splitter PBS may be provided to the beam delaying unit 124. The beam delaying unit 124 may delay the first-second beam L12 so that the pulse of the first-second beam L12 has a delay time Δt with respect to the pulse of the first-first beam L11. The pulse of the first-first beam L11 having an intensity in a specific range may not temporally overlap the pulse of the first-second beam L12 having an intensity in the specific range. The delay time Δt between the pulse of the first-first beam L11 and the pulse of the first-second beam L12 may be substantially the same as a pulse width of the pulse of the first-first beam L11, for example.

Referring to FIG. 2 again, the beam delaying unit 124 may delay the first-second beam L12 by extending an optical path of the first-second beam L12. The beam delaying unit 124 may adjust the delay time Δt (see FIG. 4) between the pulse of the first-first beam L11 and the pulse of the first-second beam L12.

The beam delaying unit 124 according to some embodiments may include one or more wave plates QWP1 and QWP2 and one or more mirrors M1 and M2. The beam delaying unit 124 according to some embodiments may include a first wave plate QWP1, a first mirror M1, a second wave plate QWP2, and a second mirror M2.

The first wave plate QWP1 may be disposed between the polarizing beam splitter PBS and the first mirror M1. The second wave plate QWP2 may be disposed between the polarizing beam splitter PBS and the second mirror M2. The polarizing beam splitter PBS may be disposed between the first wave plate QWP1 and the second wave plate QWP2. For example, the first wave plate QWP1 and the first mirror M1 may be disposed below the polarizing beam splitter PBS in the first direction X, and the second wave plate QWP2 and the second mirror M2 may be disposed above the polarizing beam splitter PBS in the first direction X. For example, the first mirror M1, the first wave plate QWP1, the polarizing beam splitter PBS, the second wave plate QWP2, and the second mirror M2 may be arranged along the first direction X.

Each of the first wave plate QWP1 and the second wave plate QWP2 may be a λ/4 wave plate (i.e., a quarter wave plate). The first wave plate QWP1 and the second wave plate QWP2 may convert the second state of the linear polarization into a first state of circular polarization and may convert the first state of the linear polarization into a second state of circular polarization. The first wave plate QWP1 and the second wave plate QWP2 may convert the first state of the circular polarization into the second state of the linear polarization and may convert the second state of the circular polarization into the first state of the linear polarization. The first state of the circular polarization may be a right-handed circular polarization (RCP) state in which the beam rotates in a counterclockwise direction and the second state of the circular polarization may be a left-handed circular polarization (LCP) state in which the beam rotates in a clockwise direction.

The polarizing beam splitter PBS may reflect the first-second beam L12, which is in the second state of the linear polarization. The first wave plate QWP1 may convert the first-second beam L12 reflected by the polarizing beam splitter PBS into the first state of the circular polarization. The first mirror M1 may reflect the first-second beam L12 passing through the first wave plate QWP1 to the first wave plate QWP1. The first-second beam L12, which is in the first state of the circular polarization, may be reflected by the first mirror M1 to have the second state of the circular polarization. The first wave plate QWP1 may convert the first-second beam L12 reflected by the first mirror M1 into the first state of the linear polarization. The polarizing beam splitter PBS may transmit the first-second beam L12 passing through the first wave plate QWP1 therethrough. The second wave plate QWP2 may convert the first-second beam L12 transmitted through the polarizing beam splitter PBS into the second state of the circular polarization. The second mirror M2 may reflect the first-second beam L12 passing through the second wave plate QWP2 to the second wave plate QWP2. The first-second beam L12, which is in the second state of the circular polarization may be reflected by the second mirror M2 to have the first state of the circular polarization. The second wave plate QWP2 may convert the first-second beam L12 reflected by the second mirror M2 into the second state of the linear polarization. The polarizing beam splitter PBS may reflect the first-second beam L12 passing through the second wave plate QWP2. The first-second beam L12, which is in the second state of the linear polarization, may be reflected by the polarizing beam splitter PBS and then output.

Meanwhile, the beam delaying unit 124 may adjust a distance D1 between the polarizing beam splitter PBS and the first mirror M1. The beam delaying unit 124 may be movable so as to adjust the distance D1. Accordingly, the delay time Δt (see FIG. 4) between the pulse of the first-first beam L11 and the pulse of the first-second beam L12 may be adjusted. For example, the delay time Δt (see FIG. 4) may be D1/C, where C is the speed of light. In the first optical apparatus 120 according to some embodiments, either the first mirror M1 or the second mirror M2 may be movable in the first direction X. As an example, the first mirror M1 may be movable in the first direction X. The distance D1 between the polarizing beam splitter PBS and the first mirror M1 may be adjusted by the movement of the first mirror M1. Accordingly, the beam delaying unit 124 may adjust a length of a path of the first-second beam L12 and adjust the delay time Δt between the pulse of the first-first beam L11 and the pulse of the first-second beam L12. As another example, a position of the first mirror M1 may be fixed, but the second mirror M2 may be movable in the first direction X.

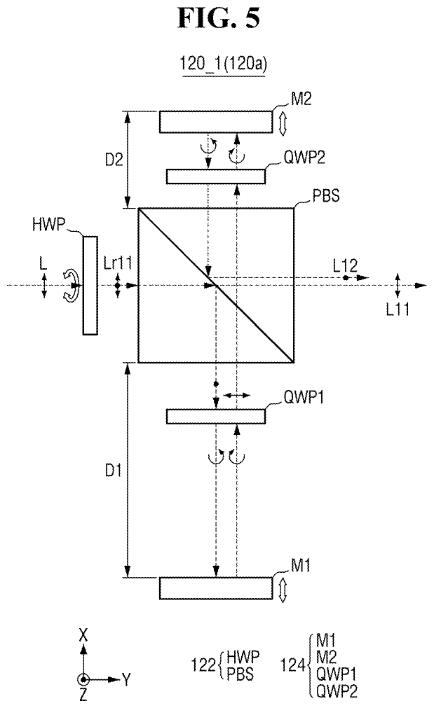

FIG. 5 is a diagram for describing an optical apparatus according to some embodiments. For convenience of explanation, contents different from those described with reference to FIGS. 1 to 4 will be mainly described.

Referring to FIG. 5, in an optical module 120_1 of a first optical apparatus 120a according to some embodiments, the second mirror M2 may be movable in the first direction X. A distance D2 between the polarizing beam splitter PBS and the second mirror M2 may be adjusted by the movement of the second mirror M2. The beam delaying unit 124 may adjust a length of a path of the first-second beam L12 and adjust the delay time Δt between the pulse of the first-first beam L11 and the pulse of the first-second beam L12 by adjusting the distance D1 and the distance D2.

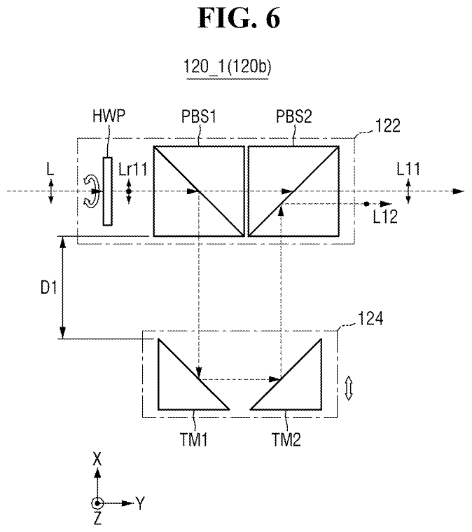

FIG. 6 a diagram for describing an optical apparatus according to some embodiments. For convenience of explanation, contents different from those described with reference to FIGS. 1 to 4 will be mainly described.

Referring to FIG. 6, in an optical module 120_1 of a first optical apparatus 120b according to some embodiments, the beam splitting unit 122 may include a wave plate HWP and a plurality of polarizing beam splitters PBS1 and PBS2. The beam splitting unit 122 may include the plurality of polarizing beam splitters PBS1 and PBS2 disposed in series. For example, the beam splitting unit 122 may include a first polarizing beam splitter PBS1 and a second polarizing beam splitter PBS2.

The first polarizing beam splitter PBS1 may receive the first changed beam Lr11. The first polarizing beam splitter PBS1 may be disposed between the wave plate HWP and the second polarizing beam splitter PBS2. The first polarizing beam splitter PBS1 and the second polarizing beam splitter PBS2 may provide the first-first beam L11 and the first-second beam L12 to different optical paths. The first polarizing beam splitter PBS1 and the second polarizing beam splitter PBS2 may transmit the beam, which is in the first state of the linear polarization, therethrough and reflect the beam, which is in the second state of the linear polarization.

In the optical module 120_1 according to some embodiments, the beam delaying unit 124 may include one or more mirror TM1 and TM2. One or more mirrors TM1 and TM2 may receive the first-second beam L12 from the beam splitting unit 122 and reflect the first-second beam L12 to the beam splitting unit 122.

In the optical module 120_1 according to some embodiments, the beam delaying unit 124 may include a first mirror TM1 and a second mirror TM2. For example, each of the first mirror TM1 and the second mirror TM2 may include a reflective surface inclined with respect to the first direction X.

The first polarizing beam splitter PBS1 may transmit the first-first beam L11, which is in the first state of the linear polarization, therethrough and reflect the first-second beam L12, which is in the second state of the linear polarization. The first-first beam L11, which is in the first state of the linear polarization, may be provided to the second polarizing beam splitter PBS2. The second polarizing beam splitter PBS2 may transmit the first-first beam L11, which is in the first state of the linear polarization, therethrough. The first-first beam L11 may pass through the first and second polarizing beam splitters PBS1 and PBS2 and be then output.

The first-second beam L12 reflected by the first polarizing beam splitter PBS1 may be provided to the beam delaying unit 124. The first mirror TM1 may reflect the first-second beam L12 reflected by the first polarizing beam splitter PBS1 to the second mirror TM2. The second mirror TM2 may reflect the first-second beam L12 reflected by the first mirror TM1 to the second polarizing beam splitter PBS2. The second polarizing beam splitter PBS2 may reflect the first-second beam L12 reflected from the second mirror TM2. The first-second beam L12, which is in the second state of the linear polarization, may be reflected by the second polarizing beam splitter PBS2 and then output.

In the optical module 120_1 according to some embodiments, the first and second mirrors TM1 and TM2 may be movable in the first direction X. Accordingly, a distance D1 between the first polarizing beam splitter PBS1 and the first mirror TM1 or a distance D1 between the second polarizing beam splitter PBS2 and the second mirror TM2 may be adjusted.

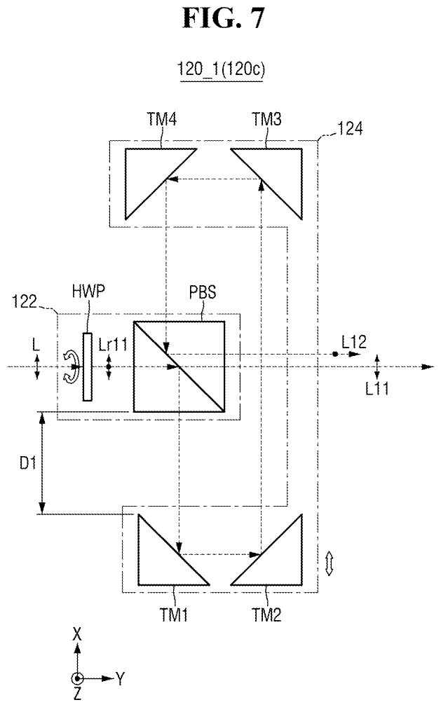

FIG. 7 a diagram for describing an optical apparatus according to some embodiments. For convenience of explanation, contents different from those described with reference to FIGS. 1 to 4 will be mainly described.

Referring to FIG. 7, in an optical module 120_1 of a first optical apparatus 120c according to some embodiments, the beam delaying unit 124 may include one or more mirrors TM1 and TM2. One or more mirrors TM1 and TM2 may receive the first-second beam L12 from the beam splitting unit 122 and reflect the first-second beam L12 to the beam splitting unit 122. For example, in the optical module 120_1 according to some embodiments, the beam delaying unit 124 may include first to fourth mirrors TM1, TM2, TM3, and TM4.

For example, the first and second mirrors TM1 and TM2 may be disposed below the polarizing beam splitter PBS in the first direction X, and the third and fourth mirrors TM3 and TM4 may be disposed above the polarizing beam splitter PBS in the first direction X. For example, each of the first to fourth mirrors TM1, TM2, TM3, and TM4 may include a reflective surface inclined with respect to the first direction X.

The first-second beam L12 reflected by the polarizing beam splitter PBS may be provided to the beam delaying unit 124. The first mirror TM1 may reflect the first-second beam L12 reflected by the polarizing beam splitter PBS to the second mirror TM2. The second mirror TM2 may reflect the first-second beam L12 reflected by the first mirror TM1 to the third mirror TM3. The third mirror TM3 may reflect the first-second beam L12 reflected by the second mirror TM2 to the fourth mirror TM4. The fourth mirror TM4 may reflect the first-second beam L12 reflected by the third mirror TM3 to the polarizing beam splitter PBS. The polarizing beam splitter PBS may reflect the first-second beam L12 reflected from the fourth mirror TM4. The first-second beam L12, which is in the second state of the linear polarization, may be reflected by the polarizing beam splitter PBS and then output.

In the optical module 120_1 according to some embodiments, the first and second mirrors TM1 and TM2 may be movable in the first direction X. Accordingly, a distance D1 between the polarizing beam splitter PBS and the first mirror TM1 may be adjusted.

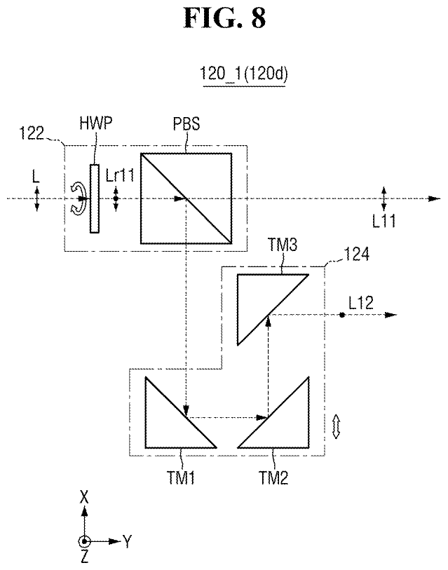

FIG. 8 a diagram for describing an optical apparatus according to some embodiments. For convenience of explanation, contents different from those described with reference to FIGS. 1 to 4 will be mainly described.

In an optical module 120_1 of a first optical apparatus 120d according to some embodiments, the beam delaying unit 124 may include one or more mirrors TM1, TM2, and TM3. One or more mirrors TM1, TM2, and TM3 may receive the first-second beam L12 from the beam splitting unit 122 and reflect the first-second beam L12 to the beam splitting unit 122. For example, in the optical module 120_1 according to some embodiments, the beam delaying unit 124 may include first to third mirrors TM1, TM2, and TM3.

For example, each of the first to third mirrors TM1, TM2, and TM3 may include a reflective surface inclined with respect to the first direction X. For example, the first to third mirrors TM1, TM2, and TM3 may be disposed below the polarizing beam splitter PBS in the first direction X. The polarizing beam splitter PBS and the third mirror TM3 may not overlap each other in the first direction X.

The first-second beam L12 reflected by the polarizing beam splitter PBS may be provided to the beam delaying unit 124. The first mirror TM1 may reflect the first-second beam L12 reflected by the polarizing beam splitter PBS to the second mirror TM2. The second mirror TM2 may reflect the first-second beam L12 reflected by the first mirror TM1 to the third mirror TM3. The third mirror TM3 may reflect and output the first-second beam L12 reflected by the second mirror TM2. The first-first beam L11 and the first-second beam L12 may be output at different positions.

In the first optical apparatus 120 according to some embodiments, the first and second mirrors TM1 and TM2 may be movable in the first direction X. Accordingly, a distance between the polarizing beam splitter PBS and the first mirror TM1 and a distance between the first mirror TM1 and the third mirror TM3 may be adjusted.

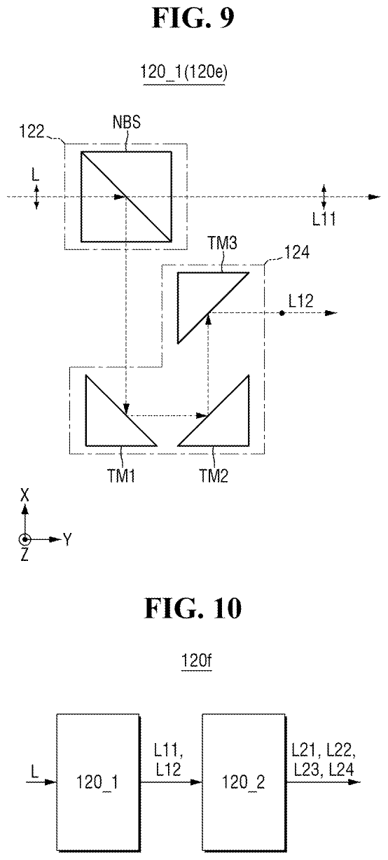

FIG. 9 is a diagram for describing an optical apparatus according to some embodiments. For convenience of explanation, contents different from those described with reference to FIG. 8 will be mainly described.

Referring to FIG. 9, in an optical module 120_1 of a first optical apparatus 120e according to some embodiments, the beam splitting unit 122 may be a non-polarizing beam splitter NBS. The non-polarizing beam splitter NBS may split the laser beam L regardless of polarization. The non-polarizing beam splitter NBS may transmit the beam, which is in the first state of the linear polarization, therethrough and reflect the beam, which is in the second state of the linear polarization.

The non-polarizing beam splitter NBS may receive the laser beam L and split the laser beam L into the first-first beam L11 and the first-second beam L12. The non-polarizing beam splitter NBS may split the laser beam L into the first-first beam L11 and the first-second beam L12 of which maximum intensities of pulses are the same as each other. The non-polarizing beam splitter NBS may transmit the first-first beam L11, which is in the first state of the linear polarization, therethrough and reflect the first-second beam L12, which is in the second state of the linear polarization. The first-first beam L11, which is in the first state of the linear polarization, may pass through the non-polarizing beam splitter NBS and be then output.

The first-second beam L12 reflected by the non-polarizing beam splitter NBS may be provided to the beam delaying unit 124. The first-second beam L12, which is in the second state of the linear polarization, may be output through the beam delaying unit 124.

FIGS. 10 to 13 are views for describing optical apparatuses according to some embodiments. FIG. 14 is a graph illustrating pulses of second-first to second-fourth beams. For convenience of explanation, contents different from those described with reference to FIGS. 1 to 9 will be mainly described.

Referring to FIG. 10, a first optical apparatus 120f according to some embodiments may include a plurality of optical modules 120_1 and 120_2. For example, the first optical apparatus 120f may include both an optical module 120_1 and an optical module 120_2. The optical module 120_1 and the optical module 120_2 may be connected to each other in series. The optical module 1201 may receive a laser beam L and output a first-first beam L11 and a first-second beam L12. The optical module 120_2 may receive the first-first beam L11 and the first-second beam L12 from the optical module 120_1 and output a second-first beam L21, a second-second beam L22, a second-third beam L23, and a second-fourth beam L24.

Each of the optical module 120_1 and the optical module 1202 may be any one of the optical modules described with reference to FIGS. 2 and 5 to 9. As an example, the optical module 120_2 may have the same configuration as the optical module 120_1. As another example, the optical module 120_2 may have a different configuration from the optical module 120_1.

As another example, the first optical apparatus 120f may include first to n-th optical modules (n is a natural number greater than 2) connected to each other in series. An m-th optical module (m is a natural number greater than 1 and smaller than n) may receive a beam from an m-1-th optical module, change a polarization state of the beam to generate a changed beam, split the changed beam into a first beam, which is in a first state of linear polarization, and a second beam, which is in a second state of linear polarization, and output the first and second beams so as to have a delay time therebetween. Each of the first to n-th optical modules (n is a natural number greater than 2) may be any one of the optical modules described with reference to FIGS. 2 and 5 to 9.

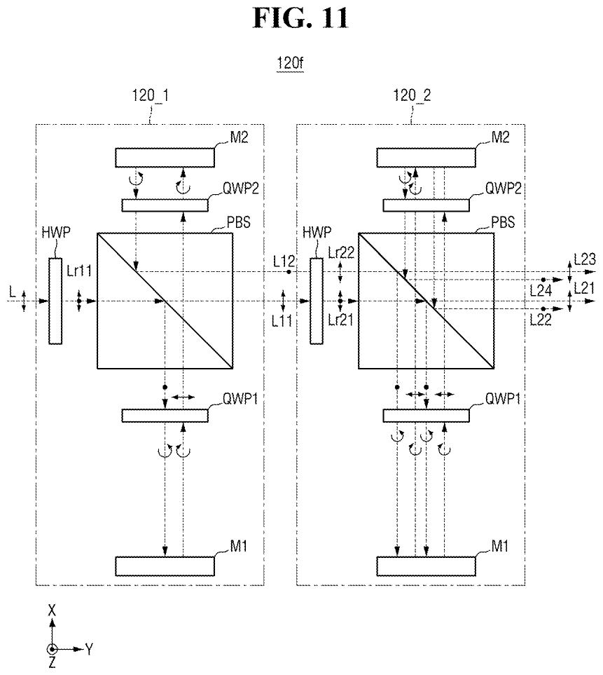

Referring to FIG. 11, each of the optical module 120_1 and the optical module 120_2 may have the same configuration as the optical module 120_1 of FIG. 2. Hereinafter, the optical module 120_2 will be described.

In the optical module 120_2, the wave plate HWP may receive the first-first beam L11 and change a polarization state of the first-first beam L11 to generate a second-first changed beam Lr21. The first changed beam Lr11 may include a second-first beam L21 and a second-second beam L22. The second-first beam L21 may be a p-polarization component of the second-first changed beam Lr21, and the second-second beam L22 may be an s-polarization component of the second-first changed beam Lr21. The second-first beam L21 may be in a first state of linear polarization and the second-second beam L22 may be in a second state of linear polarization.

The wave plate HWP may receive the first-second beam L12 and change a polarization state of the first-second beam L12 to generate a second-second changed beam Lr22. The second-second changed beam Lr22 may include a second-third beam L23 and a second-fourth beam L24. The second-third beam L23 may be a p-polarization component of the second-second changed beam Lr22, and the second-fourth beam L24 may be an s-polarization component of the second-second changed beam Lr22. The second-third beam L23 may be in a first state of linear polarization and the second-fourth beam L24 may be in a second state of linear polarization.

The wave plate HWP may generate the second-first changed beam Lr21 by rotating a polarization direction of the first-first beam L11 by 45°. The wave plate HWP may generate the second-second changed beam Lr22 by rotating a polarization direction of the first-second beam L12 by 45°.

Referring to FIG. 14, a maximum intensity A/4 of a pulse of the second-first beam L21 may be the same as a maximum intensity A/4 of a pulse of the second-second beam L22. The maximum intensity A/4 of the pulse of the second-first beam L21 and the maximum intensity A/4 of the pulse of the second-second beam L22 may be half of a maximum intensity A/2 of a pulse of the first-first beam L11. A maximum intensity A/4 of a pulse of the second-third beam L23 may be the same as a maximum intensity A/4 of a pulse of the second-fourth beam L24. The maximum intensity A/4 of the pulse of the second-third beam L23 and the maximum intensity A/4 of the pulse of the second-fourth beam L24 may be half of a maximum intensity A/2 of a pulse of the first-second beam L12.

Referring to FIG. 11 again, the polarizing beam splitter PBS may transmit the second-first beam L21 therethrough and reflect the second-second beam L22. The second-first beam L21, which is in the first state of the linear polarization, may pass through the polarizing beam splitter PBS and be then output. The polarizing beam splitter PBS may transmit the second-third beam L23 therethrough and reflect the second-fourth beam L24. The second-third beam L23, which is in the first state of the linear polarization, may pass through the polarizing beam splitter PBS and be then output.

The first wave plate QWP1 may convert the second-second beam L22 and the second-fourth beam L24 reflected by the polarizing beam splitter PBS into a first state of circular polarization. The second-second beam L22 and the second-fourth beam L24, which are in the first state of the circular polarization, may be reflected by the first mirror M1 to have a second state of the circular polarization. The first mirror M1 may reflect the second-second beam L22 and the second-fourth beam L24 passing through the first wave plate QWP1 to the first wave plate QWP1 of the optical module 120_2. The second-second beam L22 and the second-fourth beam L24, which are in the first state of the circular polarization, may be reflected by the first mirror M1 to have a second state of the circular polarization. The first wave plate QWP1 may convert the second-second beam L22 and the second-fourth beam L24 reflected by the first mirror M1 into the first state of the linear polarization. The polarizing beam splitter PBS may transmit the second-second beam L22 and the second-fourth beam L24 passing through the first wave plate QWP1 therethrough. The second wave plate QWP2 may convert the second-second beam L22 and the second-fourth beam L24 transmitted through the polarizing beam splitter PBS into a second state of circular polarization. The second mirror M2 may reflect the second-second beam L22 and the second-fourth beam L24 passing through the second wave plate QWP2 to the second wave plate QWP2. The second-second beam L22 and the second-fourth beam L24, which are in the second state of the circular polarization, may be reflected by the second mirror M2 to have a first state of the circular polarization. The second wave plate QWP1 may convert the second-second beam L22 and the second-fourth beam L24 reflected by the second mirror M2 into the second state of the linear polarization. The polarizing beam splitter PBS may reflect the second-second beam L22 and the second-fourth beam L24 passing through the second wave plate QWP2. The second-second beam L22 and the second-fourth beam L24, which are in the second state of the linear polarization, may be reflected by the polarizing beam splitter PBS and then output.

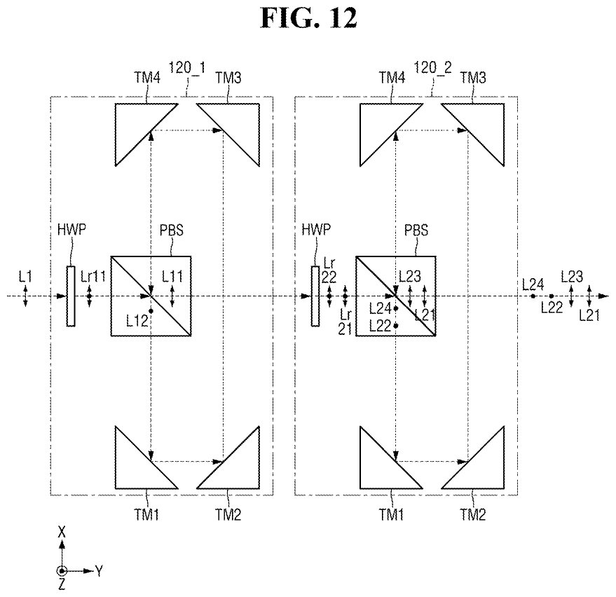

Referring to FIG. 12, each of the optical module 120_1 and the optical module 120_2 may have the same configuration as the optical module 20_1 of FIG. 7. Hereinafter, the optical module 120_2 will be described.

The wave plate HWP of the optical module 120_2 may generate a second-first changed beam Lr21 and a second-second changed beam Lr22 as described with reference to FIG. 11. In the optical module 120_2, the polarizing beam splitter PBS may transmit a second-first beam L21 and a second-third beam L23 therethrough and reflect a second-second beam L22 and a second-fourth beam L24. The second-first beam L21 and the second-third beam L23, which are in a first state of linear polarization, may pass through the polarizing beam splitter PBS and be then output.

The first mirror TM1 may reflect the second-second beam L22 and the second-fourth beam L24 reflected by the polarizing beam splitter PBS to the second mirror TM2. The second mirror TM2 may reflect the second-second beam L22 and the second-fourth beam L24 reflected by the first mirror TM1 to the third mirror TM3. The third mirror TM3 may reflect the second-second beam L22 and the second-fourth beam L24 reflected by the second mirror TM2 to the fourth mirror TM4. The fourth mirror TM4 may reflect the second-second beam L22 and the second-fourth beam L24 reflected by the third mirror TM3 to the polarizing beam splitter PBS. The second-second beam L22 and the second-fourth beam L24, which are in the second state of the linear polarization, may be reflected by the polarizing beam splitter PBS and then output.

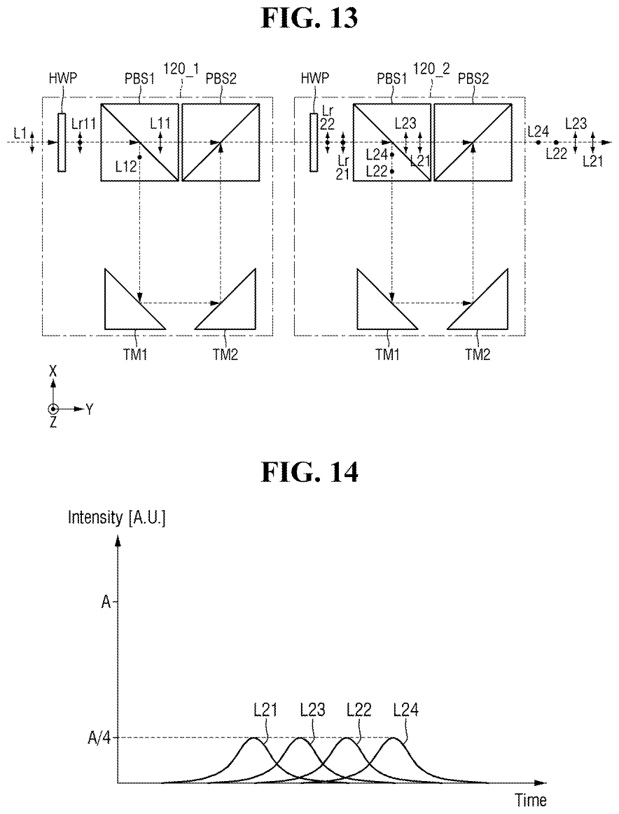

Referring to FIG. 13, each of the optical module 120_1 and the optical module 120_2 may have the same configuration as the optical module 20_1 of FIG. 6. Hereinafter, the optical module 120_2 will be described.

The wave plate HWP of the optical module 120_2 may generate a second-first changed beam Lr21 and a second-second changed beam Lr22 as described with reference to FIG. 11.

In the optical module 120_2, the first polarizing beam splitter PBS1 may transmit a second-first beam L21 and a second-third beam L23 therethrough and reflect a second-second beam L22 and a second-fourth beam L24.

The second-first beam L21 and the second-third beam L23, which are in a first state of linear polarization, may be provided to the second polarizing beam splitter PBS2. The second polarizing beam splitter PBS2 may transmit the second-first beam L21 and the second-third beam L23, which are in the first state of the linear polarization, therethrough. The second-first beam L21 and the second-third beam L23 may pass through the first and second polarizing beam splitters PBS1 and PBS2 and be then output.

The first mirror TM1 may reflect the second-second beam L22 and the second-fourth beam L24 reflected by the first polarizing beam splitter PBS1 to the second mirror TM2. The second mirror TM2 may reflect the second-second beam L22 and the second-fourth beam L24 reflected by the first mirror TM1 to the second polarizing beam splitter PBS2. The second polarizing beam splitter PBS2 may reflect the second-second beam L22 and the second-fourth beam L24 reflected from the second mirror TM2. The second-second beam L22 and the second-fourth beam L24, which are in the second state of the linear polarization, may be reflected by the second polarizing beam splitter PBS2 and then output.

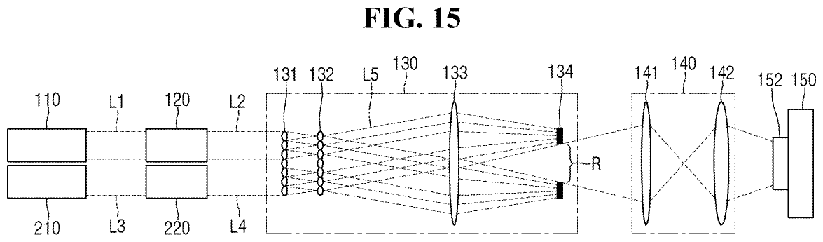

FIG. 15 is a diagram for describing a wafer processing system according to some embodiments. For convenience of explanation, contents different from those described with reference to FIGS. 1 to 14 will be mainly described.

Referring to FIG. 15, a wafer processing system according to some embodiments may include a plurality of light sources 110 and 210 and a plurality of optical apparatuses 120 and 220. For example, the plurality of light sources 110 and 210 may include first and second light sources 110 and 210, and the plurality of optical apparatuses 120 and 220 may include first and second optical apparatuses 120 and 220.

The second light source 210 may generate and output a laser beam L3 having the same intensity, the same output power, or the same pulse width as the laser beam L1. The second optical apparatus 220 may receive the laser beam L3 from the second light source 210. The second optical apparatus 220 may split the laser beam L3 and generate and output a plurality of laser beams L4 having a delay time therebetween.

As an example, the second optical apparatus 220 may include any one optical module 120_1 of the optical modules described with reference to FIGS. 2 and 5 to 9. As another example, the second optical apparatus 220 may include the plurality of optical modules 120_1 and 120_2 described with reference to FIGS. 10 to 14.

As an example, the second optical apparatus 220 may have the same configuration as the first optical apparatus 120. As another example, the second optical apparatus 220 may have a different configuration from the first optical apparatus 120.

The illumination optics 130 may receive the plurality of laser beams L2 and the plurality of laser beams L4. The illumination optics 130 may mix and homogenize the plurality of laser beams L2 and L4 with each other. The array lenses 131 and 132 may split the plurality of laser beams L2 and L4 into a plurality of laser beams L5. The condenser lens 133 may condense the plurality of laser beams L5 into an illumination area R.

The first optical apparatus 120 and the second optical apparatus 220 may output the plurality of laser beams L2 and L4 so that beams in the same state of linear polarization overlap each other to have a shape of a pulse of the first laser beam L1 or a shape of a pulse of the second laser beam L2. The first optical apparatus 120 and the second optical apparatus 220 may adjust delay times of the plurality of laser beams L2 and L4 and output the plurality of laser beams L2 and L4 of which the delay times are adjusted so that the beams in the same state of the linear polarization may overlap each other. For example, when the first optical apparatus 120 splits the first laser beam L1 to output a first beam, which is in a first state of linear polarization, and a second beam, which is in a second state of linear polarization, and the second optical apparatus 220 splits the third laser beam L3 to output a third beam, which is in a first state of linear polarization, and a fourth beam, which is in a second state of linear polarization, the first beam and the third beam may overlap each other to form a beam having the same pulse shape, same pulse width, and same energy as the first laser beam L1, and the second beam and the fourth beam may overlap each other to form a beam having the same pulse shape, same pulse width, and same energy as the second laser beam L2.

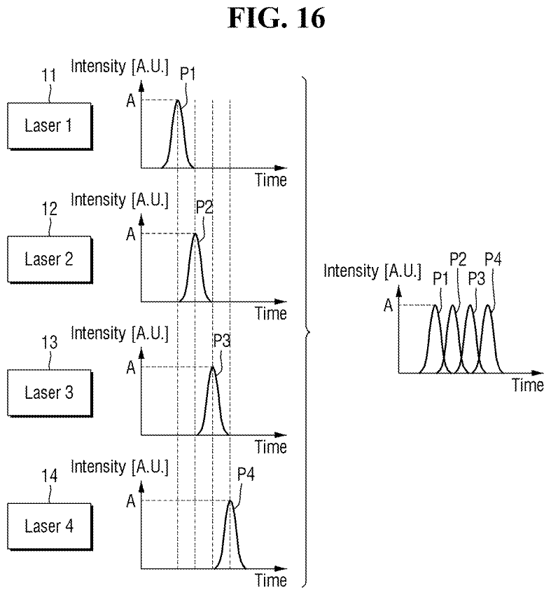

FIGS. 16 to 18 are views for describing optical apparatuses according to some embodiments. For convenience of explanation, contents different from those described with reference to FIGS. 1 to 15 will be mainly described.

Referring to FIG. 16, first to fourth light sources 11, 12, 13, and 14 may generate first to fourth laser beams P1, P2, P3, and P4, respectively. Each of the first to fourth light sources 11, 12, 13, and 14 may be the light source 110 described with reference to FIG. 1. A maximum intensity of pulses of the first to fourth laser beams P1, P2, P3, and P4 may be A.

Referring to FIGS. 1 and 16, each of first to fourth laser beams P1, P2, P3, and P4 may be split by the first and second array lenses 131 and 132. The first to fourth laser beams P1, P2, P3, and P4 split by the first and second array lenses 131 and 132 may be condensed into the illumination area R by the condenser lens 133. The split first to fourth laser beams P1, P2, P3, and P4 may overlap each other and be provided to the illumination area R.

When the first to fourth light sources 11, 12, 13, and 14 are laser light sources having coherence, an interference phenomenon occurs between the first to fourth laser beams P1, P2, P3, and P4 overlapping each other, such that interference fringes having a certain period are generated in the illumination area R. For example, the first laser beam P1 generated from the first light source 11 may be split into a first sub-beam and a second sub-beam by the first and second array lenses 131 and 132, and the first sub-beam and the second sub-beam may overlap each other by the condenser lens 133. That is, when the beam generated from one light source 11, 12, 13, or 14 is split and the split beams overlap each other, an interference phenomenon may occur between the split beams.

The interference fringes generated in the illumination area R due to such an interference phenomenon may be formed on the wafer 152 through the imaging optics 140 and may become great or small by a magnification of the imaging optics 140. The interference fringes may deteriorate uniformity of the beam provided to the wafer 152 and may cause a defect in a wafer processing process.

An intensity distribution (I(y)) of the beam formed by the overlap between the first beam and the second beam in the illumination area R may have an interference fringe shape having a period (Λ) and may be represented by Equation 1.

$$I ( y ) = {\vert E 1 \vert}^{2} + {\vert E 2 \vert}^{2} + 2 k ( E 1 \cdot E 2 ) ( cos 2 π \frac{y}{Λ} ) \qquad [ Equation 1 ]$$

Here, E1 refers to an intensity of an electric field of the first beam, E2 refers to an intensity of an electric field of the second beam, k refers to a coherence index, and y refers to a distance from the center of the illumination area on the illumination area. When laser beams output from N light sources overlap each other, ideally the coherence index (k) is improved 1/\sqrt{N} times.

In a case of a beam emitted from one light source, great interference noise may be generated in the illumination area R due to coherence of the beam during a pulse width time, and uniformity of the beam may be impaired. When beams emitted from a plurality of different light sources are temporally synchronized with and overlap each other, a pulse shape, a pulse width, energy, and the like, of the beams may be kept the same as an existing pulse shape, pulse width, energy, and the like, and since the beams are emitted from the different light sources, a coherence index becomes small, such that interference noise may be improved. The coherence noise may be improved by increasing the number of light sources, which is difficult in terms of space and cost.

However, the wafer processing system according to some embodiments may form pulses having the same shape as a beam output from an existing light source by splitting each of the beams output from the plurality of light sources into a plurality of beams that have a delay time therebetween and are in different linear polarization states by the optical apparatuses and properly mixing the plurality of beams with each other. For example, beams in the same linear polarization state may be mixed with each other. Accordingly, a beam with improved coherence may be generated.

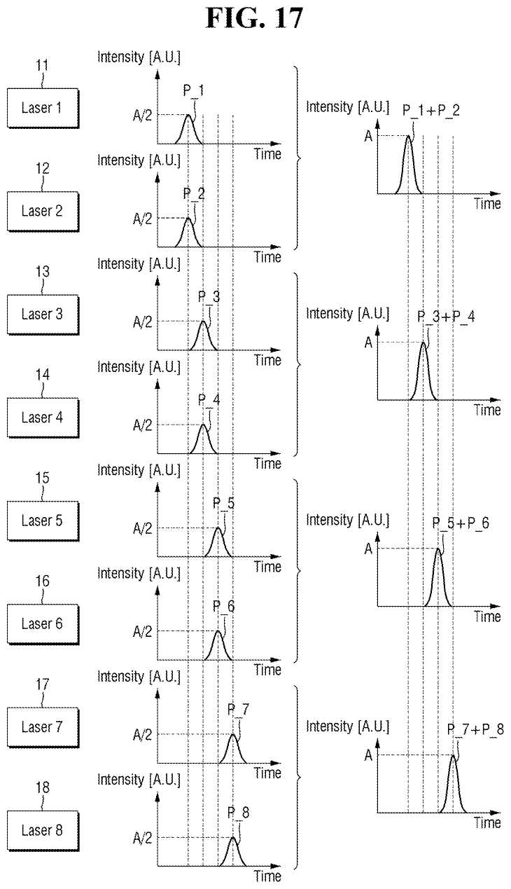

Referring to FIG. 17, first to eighth light sources 11, 12, 13, 14, 15, 16, 17, and 18 may generate first to eighth laser beams P_1, P_2, P_3, P_4, P_5, P_6, P_7, and P_8, respectively. Each of the first to eighth light sources 11, 12, 13, 14, 15, 16, 17, and 18 may be the light source 110 described with reference to FIG. 1. A maximum intensity of pulses of the first to eighth laser beams P_1, P_2, P_3, P_4, P_5, P_6, P_7, and P_8 may be A/2.

Referring to FIGS. 16 and 17, a pulse having the same shape as the first laser beam P1 may be generated by combining the first laser beam P_1 and the second laser beam P_2 with each other. A pulse having the same shape as the second laser beam P2 may be generated by combining the third laser beam P_3 and the fourth laser beam P_4 with each other. A pulse having the same shape as the third laser beam P3 may be generated by combining the fifth laser beam P_5 and the sixth laser beam P_6 with each other. A pulse having the same shape as the fourth laser beam P4 may be generated by combining the seventh laser beam P_7 and the eighth laser beam P_8 with each other. That is, the laser beams generated from

[symbol]

two light sources overlap each other, and thus, a coherence index (k) may be decreased 1/\sqrt{2} times.

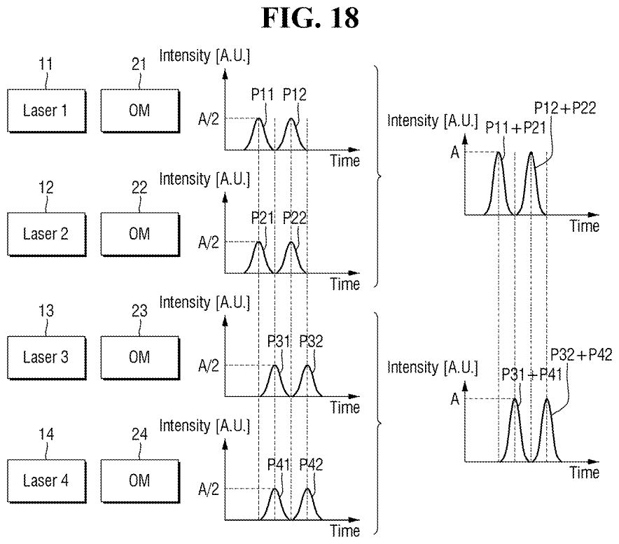

Referring to FIG. 18, first to fourth light sources 11, 12, 13, and 14 may be connected to first to fourth optical apparatuses 21, 22, 23, and 24, respectively. The first to fourth optical apparatuses 21, 22, 23, and 24 may generate first to eighth beams P11, P12, P21, P22, P31, P32, P41, and P42 by splitting first to fourth laser beams P1, P2, and P3 each generated by the first to fourth light sources 11, 12, 13, and 14, respectively. A maximum intensity of pulses of the first to eighth beams P11, P12, P21, P22, P31, P32, P41, and P42 may be A/2.

The first to fourth light sources 11, 12, 13, and 14 may be the same as the first to fourth light sources 11, 12, 13, and 14 described with reference to FIG. 16. Each of the first to fourth optical apparatuses 21, 22, 23, and 24 may be any one of the first optical apparatuses 120 described with reference to FIGS. 1 to 9.

Referring to FIGS. 16 and 18, a pulse having the same shape as the first laser beam P1 may be generated by combining the first beam P11 and the third beam P21 with each other. A pulse having the same shape as the third laser beam P3 may be generated by combining the second beam P12 and the fourth beam P22 with each other. A pulse having the same shape as the second laser beam P2 may be generated by combining the fifth beam P31 and the seventh beam P41 with each other. A pulse having the same shape as the fourth laser beam P4 may be generated by combining the sixth beam P32 and the eighth beam P42 with each other.

In this case, since the first beam P11 is provided from the first light source 11 and the second beam P12 is provided from the second light source 12 different from the first light source 11, the first beam P11 and the second beam P12 do not have coherence with each other. Accordingly, a beam P11+P21 generated by combining the first beam P11 and the third beam P21 with each other may have coherence decreased as compared with the first laser beam P1. Similarly, a beam P12+P22 generated by combining the second beam P12 and the fourth beam P22 with each other, a beam P31+P41 generated by combining the fifth beam P31 and the seventh beam P41 with each other, and a beam P32+P42 generated by combining the sixth beam P32 and the eighth beam P42 with each other may have coherence decreased as compared with the third laser beam P3, the second laser beam P2, and the fourth laser beam P4, respectively.

That is, the beams generated from the two light sources overlap each other, and thus, a coherence index (k) may be decreased 1/\sqrt{2} times. Referring to FIGS. 17 and 18, coherence noise may be improved using four light sources in the same manner as in a case of using eighth light sources.

Accordingly, the wafer processing system according to some embodiments may provide beams with improved and/or decreased coherence noise to the wafer using the optical apparatuses 21, 22, 23, and 24 without increasing the number of light sources 11, 12, 13, and 14.

By way of summation and review, aspects of embodiments of the present disclosure provide an optical apparatus that splits a laser beam into a plurality of beams and outputs the plurality of beams. Aspects of embodiments of the present disclosure also provide a wafer processing system that provides laser beams with improved or decreased coherence noise to a wafer.

That is, example embodiments include a polarization division multiplexing (PDM) (i.e., the first optical apparatus 120) between a light source and the illumination optics, so the PDM splits the laser beam from the light source to generate two laser beams that are s-polarized and p-polarized, respectively. Accordingly, a wafer processing system provided with the two laser beams that are s-polarized and p-polarized may have improved and/or decreased coherence noise without increasing the number of light sources.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A wafer processing system, comprising:
an optical apparatus including a beam splitter and a beam delayer,
wherein:
the beam splitter is configured to receive a laser beam and to split the laser beam into a first beam in a first state of linear polarization and a second beam in a second state of linear polarization; and
the beam delayer is configured to delay the second beam so that a pulse of the second beam has a delay time with respect to a pulse of the first beam.

2. The wafer processing system as claimed in claim 1, wherein the beam splitter includes:
a wave plate configured to change a polarization state of the laser beam to generate a changed beam including the first beam and the second beam; and
a first polarizing beam splitter configured to pass the first beam therethrough and to reflect the second beam to the beam delayer.

3. The wafer processing system as claimed in claim 2, wherein the beam delayer includes:
a first mirror;
a first wave plate between the beam splitter and the first mirror;
a second mirror; and
a second wave plate between the beam splitter and the second mirror,
wherein:
the first beam in the first state of linear polarization split by the beam splitter passes through the first polarizing beam splitter, and
the second beam in the second state of linear polarization split by the beam splitter:
reflected to the first wave plate by the beam splitter,
converted into circularly polarized light by the first wave plate and is provided to the first mirror,
reflected by the first mirror and provided to the first wave plate,
converted into the first state of the linear polarization by the first wave plate and is provided to the first polarizing beam splitter,
passes through the first polarizing beam splitter and is provided to the second wave plate,
converted into circularly polarized light by the second wave plate and is provided to the second mirror,
reflected by the second mirror and provided to the second wave plate,
converted into the second state of the linear polarization by the second wave plate and provided to the first polarizing beam splitter, and
reflected by the first polarizing beam splitter.

4. The wafer processing system as claimed in claim 2, wherein:
the beam splitter further includes a second polarizing beam splitter,
the beam delayer reflects the second beam reflected by the first polarizing beam splitter to the second polarizing beam splitter, and
the second polarizing beam splitter passes the first beam passing through the first polarizing beam splitter therethrough and reflects the second beam reflected by the beam delayer.

5. The wafer processing system as claimed in claim 2, wherein the wave plate is rotatable.

6. The wafer processing system as claimed in claim 1, wherein the beam delayer is movable so as to adjust a distance between the beam splitter and the beam delayer.

7. The wafer processing system as claimed in claim 1, wherein the beam delayer includes at least one mirror configured to receive the second beam from the beam splitter.

8. The wafer processing system as claimed in claim 7, wherein the at least one mirror is configured to reflect the second beam from the beam splitter back toward the beam splitter.

9. The wafer processing system as claimed in claim 1, wherein the beam splitter includes a non-polarizing beam splitter.

10. The wafer processing system according to claim 1, wherein the delay time between the pulse of the second beam and the pulse of the first beam is a pulse width of the pulse of the first beam.

11. A wafer processing system, comprising:
a stage configured to support a wafer;
a first light source configured to generate a first laser beam;
a first optical apparatus configured to receive the first laser beam and output a first beam and a second beam;
an illumination optics configured to homogenize the first beam and the second beam to generate homogenized beams; and
an imaging optics configured to image the homogenized beams on the wafer,
wherein:
the first beam is in a first state of linear polarization,
the second beam is in a second state of linear polarization, and
the first beam and the second beam have a delay time therebetween.

12. The wafer processing system as claimed in claim 11, wherein the first optical apparatus is configured to:
provide the first beam to a first optical path, and
provide the second beam to a second optical path different from the first optical path.

13. The wafer processing system as claimed in claim 11, wherein:
the first beam includes a second-first beam and a second-third beam,
the second beam includes a second-second beam and a second-fourth beam, and
the first optical apparatus includes:
a first optical module configured to change a polarization state of the first laser beam to generate a changed beam including a first-first beam and a first-second beam and output the first-first beam and the first-second beam; and
a second optical module configured to change a polarization state of the first-first beam to generate a second-first changed beam including the second-first beam and the second-second beam, to change a polarization state of the first-second beam to generate a second-second changed beam including the second-third beam and the second-fourth beam, and to output the second-first to second-fourth beams.

14. The wafer processing system as claimed in claim 13, wherein a configuration of the first optical module is the same as a configuration of the second optical module.

15. The wafer processing system as claimed in claim 13, wherein a configuration of the first optical module is different from a configuration of the second optical module.

16. The wafer processing system as claimed in claim 11, wherein a maximum intensity of a pulse of the first beam is the same as a maximum intensity of a pulse of the second beam.

17. The wafer processing system as claimed in claim 11, further comprising:
a second light source configured to generate a second laser beam; and
a second optical apparatus configured to receive the second laser beam and output a third beam and a fourth beam,
wherein:
the illumination optics is configured to homogenize the first to fourth beams to generate homogenized beams,
the third beam is in the first state of linear polarization, and
the fourth beam is in the second state of linear polarization.

18. A wafer processing system, comprising:
a stage configured to support a wafer;
a light source configured to generate a laser beam;
an optical apparatus configured to receive the laser beam and output a first beam and a second beam;
an illumination optics configured to homogenize the first beam and the second beam to generate homogenized beams; and
an imaging optics configured to image the homogenized beams on the wafer,
wherein the optical apparatus includes:
a beam splitter configured to split the laser beam into the first beam and the second beam; and
a beam delayer configured to delay the second beam so that a pulse of the second beam has a delay time with respect to a pulse of the first beam, and
wherein the beam delayer is movable so as to adjust a distance between the beam splitter and the beam delayer.

19. The wafer processing system as claimed in claim 18, wherein the beam delayer includes a plurality of mirrors, at least some of the plurality of mirrors being movable so as to adjust distances from the beam splitter.

20. The wafer processing system as claimed in claim 18, wherein the beam delayer includes at least one wave plate configured to change a polarization state of the first beam and a polarization state of the second beam.
